(19) United States
(12) Patent Application Publication
(10) Pub. No.: US 2009/0236526 A1
(43) Pub. Date: Sep. 24, 2009

(54) INFRARED RAY SENSOR ELEMENT

(75) Inventors: Keita Sasaki, Yokohama-Shi (JP); Hiroto Honda, Yokohama-Shi (JP); Hideyuki Funaki, Tokyo (JP); Ikuo Fujiwara, Yokohama-Shi (JP); Kazuhiro Suzuki, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/405,497

(22) Filed: Mar. 17, 2009

(30) Foreign Application Priority Data
Mar. 24, 2008 (JP) 2008-075420

(51) Int. Cl. H01L 27/14

(52) U.S. Cl. 250/338.4; 257/E27.122

(57) ABSTRACT

An infrared ray sensor element includes: a first signal wiring part including a first signal wire and provided on a first region of a semiconductor substrate different from a region on which a concave part is provided; a second signal wiring part including a second signal wire and provided on the first region so as to intersect the first signal wiring part; a supporter including a support wiring part disposed over the concave part, and including a first wire electrically connected at a first end thereof to the first signal wire, and a second wire insulated from the first wire, disposed in parallel with the first wire, and electrically connected at a first end thereof to the second signal wire; a thermoelectric transducer electrically connected to second ends of the first and second wires; an infrared ray absorption layer provided over the thermoelectric transducer; and a detection cell provided over the concave part.

### CROSS-REFERENCE TO RELATED APPLICATION

This application is based upon and claims the benefit of priority from prior Japanese Patent Application No. 2008-75420 filed on Mar. 24, 2008 in Japan, the entire contents of which are incorporated herein by reference.

### BACKGROUND OF THE INVENTION

1. Field of the Invention

The present invention relates to an infrared ray sensor element of uncooled type.

2. Related Art

The infrared ray sensor element of uncooled type (thermal type) is an element which absorbs infrared rays by using an infrared ray absorption layer, converts the infrared rays to heat, and converts the heat to an electric signal by using a thermoelectric transducer. In the uncooled infrared ray sensor element, a surface fine structure or bulk fine structure forming technique is utilized to thermally isolate the infrared ray absorption layer and the thermoelectric transducer from an external system. A cooled (quantum type) infrared ray sensor element needs an expensive large-sized cooler, whereas the uncooled infrared ray sensor element has a merit of small size and inexpensiveness.

As one of methods for improving the sensitivity of the uncooled infrared ray sensor element, there is a method of preventing the heat converted by the infrared ray absorption layer from escaping from the thermoelectric transducer to the external system. Typically in the uncooled infrared ray sensor element mounted on a vacuum package, the thermoelectric transducer is supported on a hollow structure over a cavity part of a semiconductor substrate by a supporter. In the heat transportation from the thermoelectric transducer to the external system, therefore, heat transportation owing to heat conduction through the supporter is dominant. For raising the thermal insulation of the thermoelectric transducer, therefore, the section area of the supporter made of a material having a low thermal conductivity is made smaller (see, for example, JP-A 2006-162470 (KOKAI)) and its length is made longer (see, for example, JP-A 2006-300816 (KOKAI)) in the layout.

For improving the thermal insulation characteristics of the supporter in the uncooled infrared ray sensor, it becomes necessary to make the sectional area of the supporter smaller and its length longer in the layout. However, the fine structure is already formed and it is difficult to implement further remarkable sensitivity improvement by contriving the layout of the supporter.

In the conventional uncooled infrared ray sensor element, a thin film supporter as described in JP-A 2006-162470 (KOKAI) is considered to be effective for improving the thermal insulation characteristics. If the section area of the supporter is made further small for further raising the sensitivity, however, there is a possibility that unexpected strain will be caused by residual stress. Since the mechanical rigidity also becomes weak, there is also a possibility that unexpected destruction will be caused by an external shock or degradation with the passage of time, resulting in a problem in reliability. Laying out the supporter so as to be rotation symmetrical as described in JP-A 2006-300816 (KOKAI) is considered to be effective for preventing strain in the supporter because internal stress applied to the central part balance. However, the internal stress applied to the central part does not balance and strain is caused, especially because of mask misalignment in a supporter forming process. For example, if a wiring part is biased by 0.1 μm when the width of the supporter is 1 μm, great strain is caused. Therefore, alignment precision of less than 0.1 μm is required. As means for improving the strain and mechanical rigidity, forming the supporter of a thick film is conceivable. Since the method is contradictory to the method for improving the thermal insulation characteristics, however, the sensitivity falls.

### SUMMARY OF THE INVENTION

The present invention has been made in view of these circumstances, and an object of thereof is to provide an uncooled infrared ray sensor element having a supporter which is suppressed in thermal insulation falling as much as possible, little in strain caused by residual stress, and strong in mechanical rigidity.

An infrared ray sensor element according to an aspect of the present invention includes a semiconductor substrate having a concave part provided on a surface thereof, a first signal wiring part provided on a region of the semiconductor substrate different from a region on which the concave part is provided, the first signal wiring part including a first signal wire, a second signal wiring part provided on a region of the semiconductor substrate different from the region on which the concave part is provided so as to intersect the first signal wiring part, the second signal wiring part including a second signal wire, a supporter including a support wiring part disposed over the concave part, the support wiring part including a first wire electrically connected at a first end thereof to the first signal wire, and a second wire insulated from the first wire, disposed in parallel with the first wire, and electrically connected at a first end thereof to the second signal wire, a thermoelectric transducer electrically connected to second ends of the first and second wires, an infrared ray absorption layer provided over the thermoelectric transducer to absorb infrared rays and thermally connected to the thermoelectric transducer, and a detection cell provided over the concave part and supported by the supporter.

### BRIEF DESCRIPTION OF THE DRAWINGS

FIGS. 1A and 1B are diagrams showing an infrared ray sensor element according to an embodiment of the present invention;

FIGS. 2 to 7 are sectional views showing manufacturing processes of an infrared ray sensor element according to an embodiment;

FIG. 8 is a sectional view showing a configuration of a first concrete example of a supporter;

FIG. 9 is a sectional view showing a configuration of a first concrete example of a supporter;

FIG. 10 is a sectional view showing a configuration of a first concrete example of a supporter;

FIG. 11 is a sectional view showing a configuration of a first concrete example of a supporter;

FIG. 12 is a plan view of an infrared ray sensor element according to a first modification of an embodiment;

FIG. 13 is a plan view of an infrared ray sensor element according to a second modification of an embodiment; and

FIG. 14 is a plan view of an infrared ray sensor element according to a third modification of an embodiment.

### DESCRIPTION OF THE EMBODIMENTS

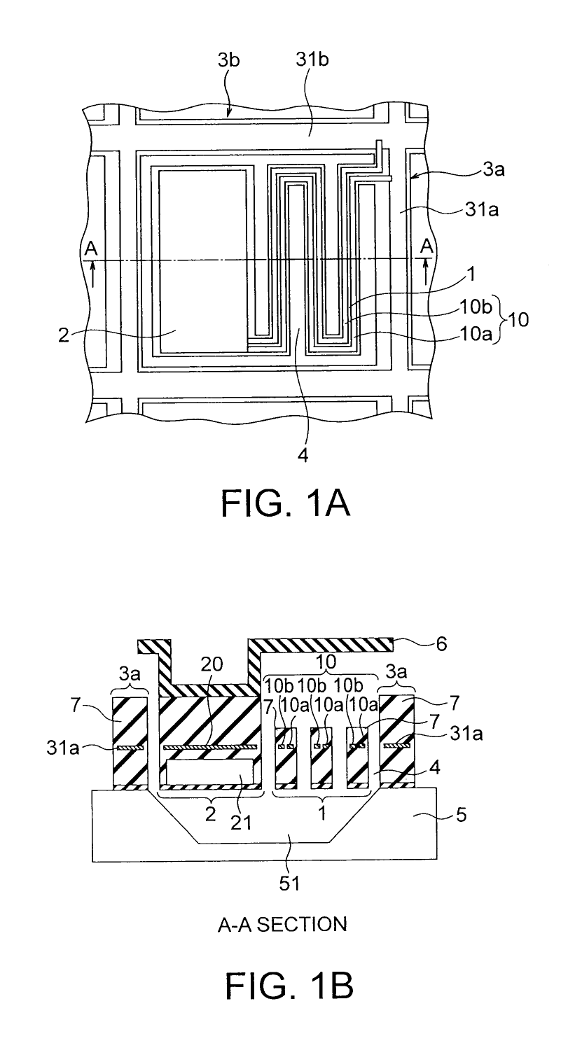

An infrared ray sensor element according to an embodiment of the present invention is shown in FIGS. 1A and 1B. FIG. 1A is a plan view of the infrared ray sensor element according to the present embodiment. FIG. 1B is a sectional view obtained by cutting the infrared ray sensor element along a cutting line A-A shown in FIG. 1A. In FIG. 1A, illustration of an infrared ray absorber 6 is omitted to make it possible to appreciate the general configuration. The infrared ray sensor element according to the present embodiment includes a supporter 1, a detection cell 2, and signal wiring parts 3a and 3b arranged in a lattice form. A plurality of signal wiring parts 3a are formed on a semiconductor substrate 5 via an insulation film in a longitudinal direction in FIG. 1A. A plurality of signal wiring parts 3b are formed in a lateral direction in FIG. 1A so as to intersect the signal wiring parts 3a.

In the signal wiring part 3a, a signal wire 31 covered by a protection insulation film 7 is provided. In the signal wiring part 3b, a signal wire 31b covered by a protection insulation film 7 is provided in the same way. The signal wire 31a and the signal wire 31b are insulated from each other at their intersection by the protection insulation film 7. A cavity part (concave part) 51 is provided on a surface of the semiconductor substrate 5 surrounded by the signal wiring parts 3a and 3b. And the supporter 1 and the detection cell 2 are disposed over the concave part 51. The supporter 1 takes a winding shape. One end of the supporter 1 is coupled to the signal wiring part 3a, and the other end of the supporter 1 is coupled to the detection cell 2. The detection cell 2 is supported so as to float in midair of the concave part 51 by only the supporter 1. A wiring part 10 covered by the protection insulation film 7 is provided in the supporter 1. The wiring part 10 has two wires 10a and 10b insulated by the protection insulation film 7. One end of the wire 10a is electrically connected to the signal wire 31a, and the other end of the wire 10a is electrically connected to the detection cell 2. One end of the wire 10b is electrically connected to the detection cell 2, and the other end of the wire 10b is electrically connected to the signal wire 31b. In the present embodiment, the concave part 51 is provided for each of intersections of the signal wiring parts 3a and 3b. The supporter 1 and the detection cell 2 are provided so as to correspond to each of the concave parts 51. In other words, the detection cells 2 are provided in a matrix form, and the concave part 51 is provided for each of the detection cells 2.

The detection cell 2 includes a thermoelectric transducer 21, a cell wiring part 20, and a protection insulation film 7 formed of an insulation material which covers surrounding of the thermoelectric transducer 21 and the cell wiring part 20. As a matter of fact, the thermoelectric transducer 21 and the cell wiring part 20 are in mutual electric conduction. However, this is omitted in FIG. 1B. The infrared ray absorber 6 having an umbrella structure is formed over the detection cell 2 so as to cover up to the signal wiring parts 3a and 3b. The infrared ray absorber 6 is formed of an insulation material such as silicon dioxide or silicon nitride, and thermally connected to the detection cell 2 via the protection insulation film 7.

The whole of the infrared ray element is vacuum-packaged, and the spacing between the infrared ray absorber 6 and the detection cell 2 and the cavity part 51 is brought into the vacuum state. The thermal insulation property of the detection cells 2 is improved and the sensitivity is raised by thus placing the detection cell 2 separated from the semiconductor substrate 5 in the vacuum.

The thermoelectric transducer 21 has a pn junction, and reads out a change of a forward voltage or current under the condition of constant current or voltage by utilizing the temperature dependence of the forward characteristics of the p-n junction. Denoting incident infrared ray power per unit area by I_{light}, an absorption efficiency by γ, an infrared ray absorption area per unit pixel by A_{D}, thermal conductance from the detection cell 2 to the semiconductor substrate 5 by Gₜₕ, and a thermoelectric transducer coefficient by dV/dT, an output signal of the thermoelectric transducer 21 is represented by the following expression (1).

(I_{light}A_{Dγ}/Gₜₕ) (dV/dT) (1)

In the expression (1), Gₜₕ is thermal conductance of the supporter 1 and Gₜₕ is represented by the following expression (2).

Gₜₕ=κNA/L (2)

In the expression (2), κ is thermal conductivity which depends upon the material of the supporter 1, A is a cross section area of the supporter 1, L is a length of the supporter 1, and N is the number of wires in the supporter 1.

As evident from the expression (1), the sensitivity of the infrared ray sensor element is in inverse proportion to the thermal conductance Gₜₕ between the detection cell 2 and the semiconductor substrate 5. Since the detection cell 2 and the supporter 1 are thermally isolated from the semiconductor substrate 5 and the signal wiring parts 3a and 3b by the cavity part 51 provided on the surface of the semiconductor substrate 5, therefore, the sensitivity of the infrared ray sensor element can be improved.

As evident from the expression (2), the thermal conductance greatly depends on the structure of the supporter 1. In the infrared ray sensor element in which the detection cell 2 is supported by the supporter 1 having one wire as in the present embodiment, the width of the supporter 1 can be formed so as to be twice as compared with, for example, an infrared ray sensor element in which the detection cell is supported by a supporter having two wires, provided that the thermal conductance is made equal. As a result, the mechanical strength can be improved and the strain can be suppressed. Furthermore, since it becomes possible to lengthen the length L of the supporter 1 by providing the supporter 1 with the winding shape as in the present embodiment, the thermal conductance can be made small, resulting in excellent thermal insulation characteristics. As a result, an infrared ray sensor element having high reliability and high sensitivity can be obtained. By the way, it is desirable to form the wires 10a and 10b of titanium having low thermal conductivity or titanium nitride.

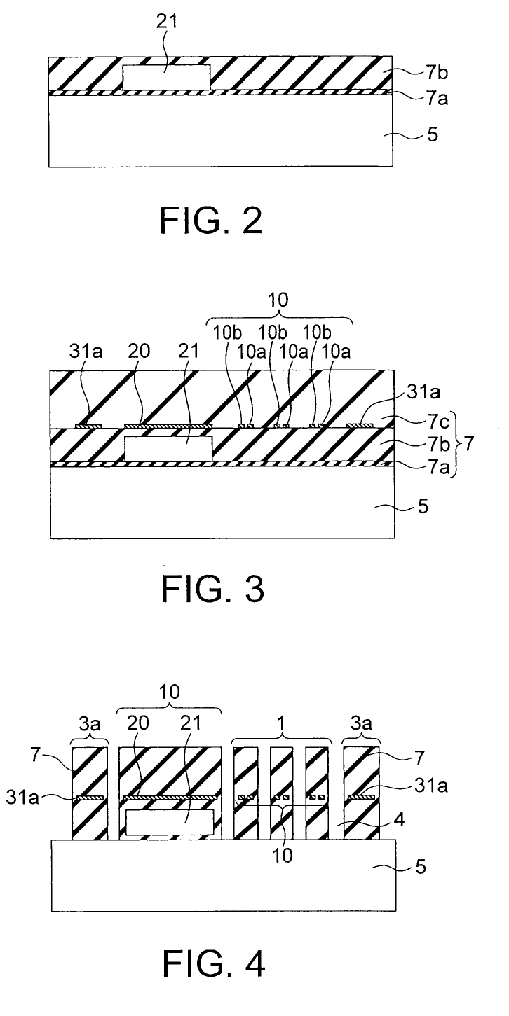

A manufacturing method of the infrared ray sensor element according to the present embodiment will now be described with reference to FIGS. 2 to 7.

FIGS. 2 to 7 are sectional views showing manufacturing processes of the infrared ray sensor element according to the present embodiment.

First, an insulation film 7a is formed on the semiconductor substrate 5. The thermoelectric transducer 21 is formed on the insulation film 7a. An insulation film 7b is formed so as to cover the thermoelectric transducer 21 (FIG. 2). If a SOI substrate is used as the semiconductor substrate 5, a buried oxide film of the SOI substrate may be used the insulation film 7a. The thermoelectric transducer 21 is, for example, a pn diode which uses single crystal silicon as its material. The insulation film 7b formed so as to cover the thermoelectric transducer 21 is formed of, for example, silicon dioxide, and the insulation film 7b acts as a device isolation region. The insulation films 7a and 7b constitute the protection insulation film 7.

Subsequently, a plurality of signal wires 31b (not illustrated) are formed by forming a conductive material film on the insulation film 7b and patterning the conductive material film. Thereafter, a first insulation film (not illustrated) is formed so as to cover these signal wires 31b. And a plurality of signal wires 31a, the cell wiring part 20, and the wiring part 10 are formed by forming a conductive material film on the insulation film and patterning the conductive material film. By the way, the wiring part 10 includes the wire 10a and the wire 10b. The signal wires 31a, the cell wiring part 20, and the wiring part 10 are covered by a second insulation film 7c. The insulation films 7a and 7b, the first insulation film, and the second insulation film 7c constitute the protection insulation film 7.

Subsequently, in order to form the cavity part 51, etching holes 4 which reach the surface of the semiconductor substrate 5 are formed through the protection insulation film 7 by anisotropic etching such as, for example, RIE, and the surface of the semiconductor substrate 5 is exposed (FIG. 4). In this process, a region in which the detection cell 2 is formed and a region in which the supporter 1 is formed are separated from each other, and the signal wiring parts 3a and 3b are demarcated.

Furthermore, patterning of the supporter 1 is conducted in this process. This patterning may be conducted according to conditions such as the size of the detection cell 2, the infrared ray sensor element size, and the width of the supporter 1 besides the shape of the supporter 1 shown in FIG. 1(b). As for a resist exposure process for forming the etching holes 4, a strict mask alignment precision is demanded in general. In addition, a part of the protection insulation film 7 in the supporter 1 may be shaved in the depth direction by the anisotropic etching such as RIE. As a result, the thermal conductance of the supporter 1 can be lowered.

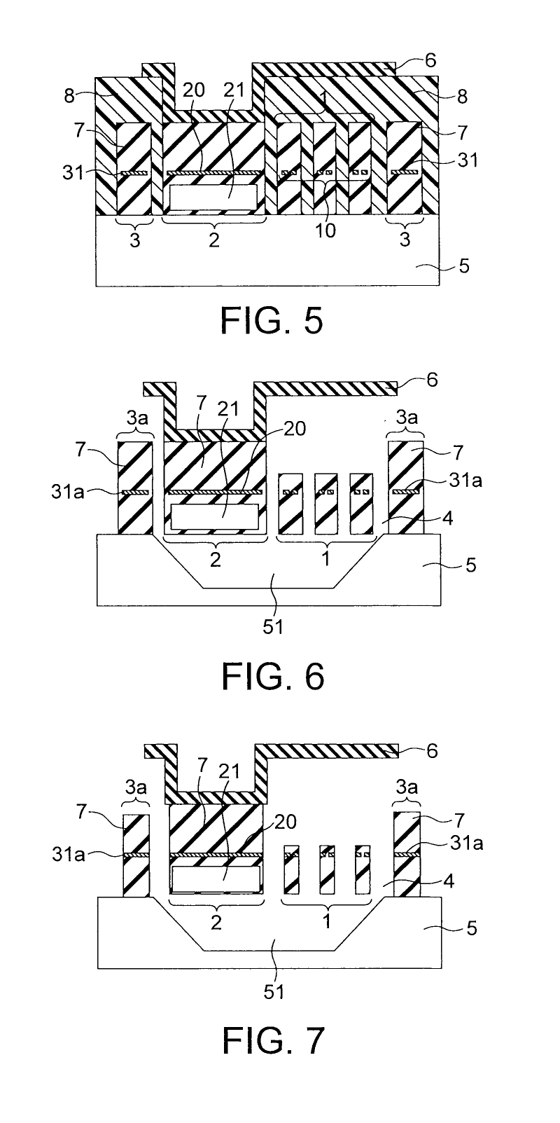

Subsequently, as shown in FIG. 5, a sacrifice layer is formed on the whole face so as to bury the etching holes 4. Thereafter, an opening is formed by removing a part of the sacrifice layer 8 over the detection cell 2. Subsequently, a film of an insulation material is formed so as to bury the opening and patterned. As a result, the infrared ray absorber 6 formed of the insulation material is formed over the detection cell 2 and the sacrifice layer 8. As for the infrared ray absorber 6, for example, an insulation material such as silicon dioxide or silicon nitride is used. Besides, a material having absorption sensitivity to infrared rays (˜10 μm) may also be used.

Subsequently, as shown in FIG. 6, the infrared ray absorber 6 is formed so as to have the umbrella structure by etching the sacrifice layer 8, and the infrared ray absorber 6 is connected to only the detection cell 2 via the protection insulation film 7. After the removal of the sacrifice layer 8, the semiconductor substrate 5 is gradually etched from the bottom face of the etching holes, and the cavity part 51 is formed. As for etching solution used in this process, for example, an anisotropic etching solution such as TMAH or KOH is used.

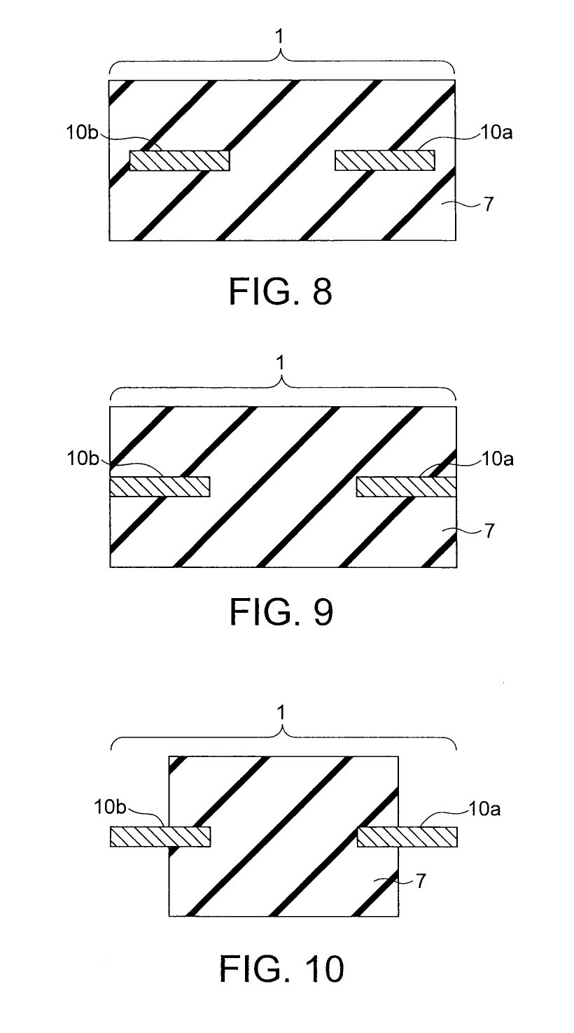

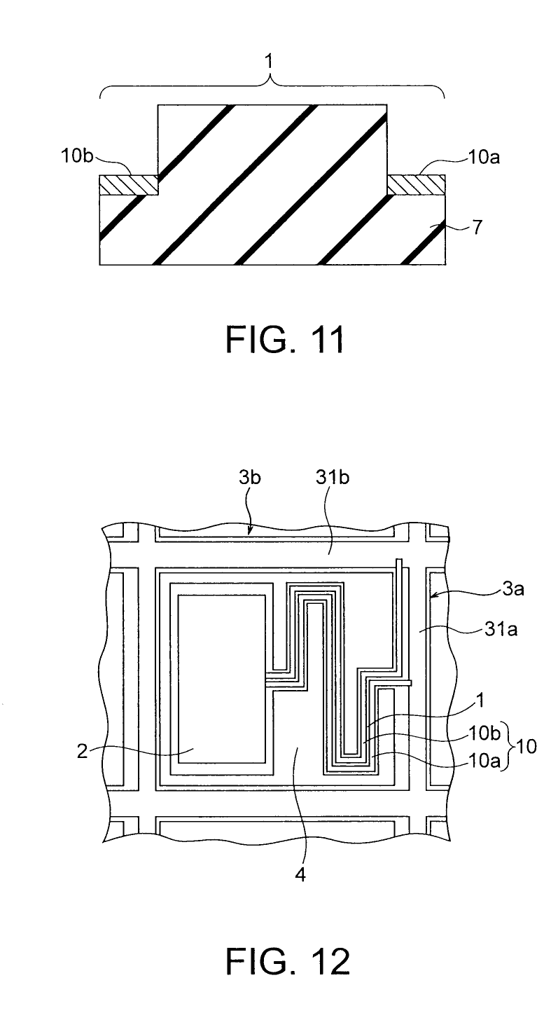

After the cavity part 51 is formed, slimming processing is conducted to shape the shape of the wiring part 10 included in the supporter 1 (see FIG. 7). For example, if the protection insulation film 7 is formed of silicon dioxide, slimming is conducted by fluoric acid processing to lower the thermal conductance. The wires 10a and 10b may be configured so as to be covered completely by the protection insulation film 7 as shown in FIG. 8. The wires 10a and 10b may be configured so as to be exposed only at their first side faces as shown in FIG. 9. The wires 10a and 10b may be configured so as to be exposed at their first side faces and parts of their top and bottom faces, as shown in FIG. 10. The wires 10a and 10b may be configured so as to be exposed at their first side faces and only parts of their top faces (or bottom faces) as shown in FIG. 11. It is necessary to implement these configurations in a range in which film peeling off of the protection insulation film 7 and mechanical strength withstand the specifications. If fluoric acid is used in slimming processing, then the configurations shown in FIGS. 8 to 11 can be formed easily by prolonging the processing time, because there are selection ratio of etching rate in the wires 10a and 10b of the supporter 1 and the protection insulation film 7.

In the present embodiment, the detection cell 2 is thus supported by the supporter 1 including the support wiring part 10 which has two wires electrically separated. Therefore, the width of the supporter 1 can be formed widely without lowering the thermal conductance and it becomes possible to increase the mechanical strength. As a result, a fear of lowering of the thermal conductance caused by thermal shortening of the supporter 1 is eliminated. Therefore, a robust uncooled infrared ray sensor element can be fabricated without a fear of lowering of the sensitivity of the detection cell 2.

Even if the symmetry of the section of the supporter 1 is lost by mask misalignment when forming the supporter 1, the stress strain is mitigated as compared with the conventional art because the width of the supporter 1 is wide. Especially in the section structure in which the side faces of the support wiring part 10 are exposed by slimming in the fluoric acid processing, there is no stress strain in the horizontal direction and there is no fear of thermal short-circuiting of the supporter 1. Therefore, mask alignment precision is not demanded so strictly when forming the supporter 1, and simplification of the manufacturing process and improvement of the yield can be attained.

In addition, an additional effect will now be described. The width of the supporter 1 in the present embodiment is narrower than the width sum of the two supporters of the conventional infrared ray sensor element supported by the two supporters, and the area of the regions of the etching holes 4 forming the supporter 1 is also reduced. Therefore, the infrared ray sensor element can be made fine without reducing the thermal conductance, and the cost can be reduced.

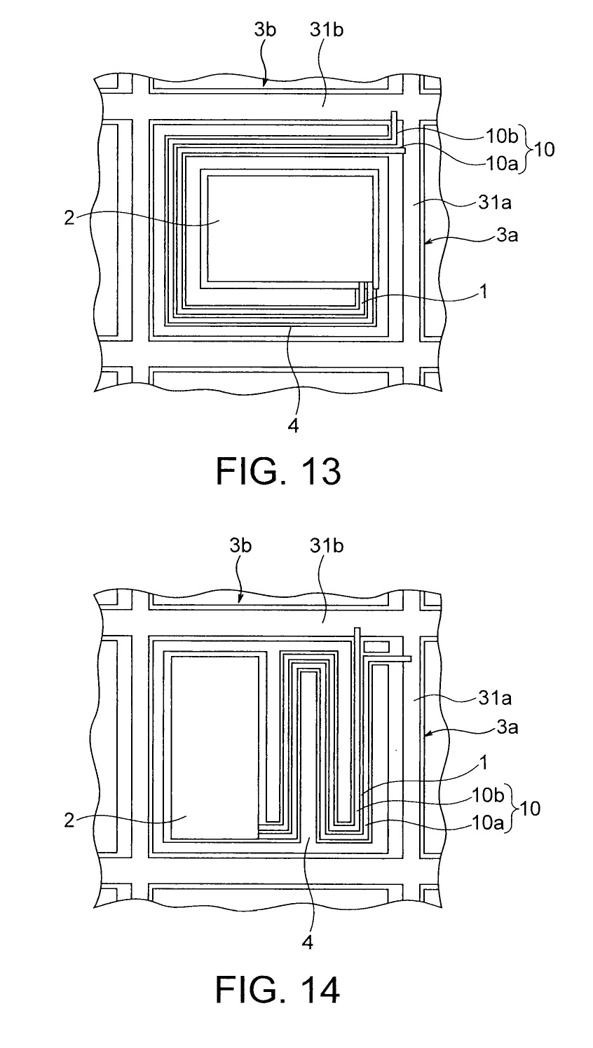

In the present embodiment, the supporter 1 takes the winding shape and connection to the signal wiring part 3a is conducted near the intersection of the signal wiring part 3a and the signal wiring part 3b. As in a first modification shown in FIG. 12, however, it is also possible to conduct the connection to the signal wiring part 3a near the center of the signal wiring part 3a and reduce the length of the winding to approximately half. As in a second modification shown in FIG. 13, the supporter 1 may be configured so as to surround three peripheral sides of the detection cell 2. As in a third modification shown in FIG. 14, the supporter 1 may be coupled to both the signal wiring part 3a and the signal wiring part 3b.

According to an embodiment of the present invention, it is possible to provide an uncooled infrared ray sensor element having a supporter which is suppressed in thermal insulation falling as much as possible, little in strain caused by residual stress, and strong in mechanical rigidity, as heretofore described.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concepts as defined by the appended claims and their equivalents.

What is claimed is:

1. An infrared ray sensor element comprising:
a semiconductor substrate having a concave part provided on a surface thereof;
a first signal wiring part provided on a region of the semiconductor substrate different from a region on which the concave part is provided, the first signal wiring part including a first signal wire;
a second signal wiring part provided on a region of the semiconductor substrate different from the region on which the concave part is provided so as to intersect the first signal wiring part, the second signal wiring part including a second signal wire;
a supporter including a support wiring part disposed over the concave part, the support wiring part including a first wire electrically connected at a first end thereof to the first signal wire, and a second wire insulated from the first wire, disposed in parallel with the first wire, and electrically connected at a first end thereof to the second signal wire;
a thermoelectric transducer electrically connected to second ends of the first and second wires;
an infrared ray absorption layer provided over the thermoelectric transducer to absorb infrared rays and thermally connected to the thermoelectric transducer; and
a detection cell provided over the concave part and supported by the supporter.

2. The element according to claim 1, wherein the supporter has insulation films formed respectively above and below the support wiring part, and side faces of the two wires on the opposite side from opposed side faces of the two wires are exposed from side faces of the supporter.

3. The element according to claim 2, wherein in the insulation films formed respectively above and below the support wiring part, at least one insulation film has a width is in a range of 0.5 to 1 times a maximum width of the supporter.

4. The element according to claim 1, wherein the first and second wires are formed of titanium or titanium nitride.

5. The element according to claim 1, wherein the supporter takes a winding shape.

6. The element according to claim 1, wherein the supporter is coupled to only the first signal wiring part, and
a place of the coupling is close to an intersection region of the first and second signal wiring parts.

7. The element according to claim 1, wherein the supporter is formed so as to three peripheral sides of the detection cell.

8. The element according to claim 1, wherein
each of the first and second signal wiring parts is provided in a plurality of number,
the concave part is provided in a region surrounded by the first and second signal wiring parts, and
the supporter and the detection cell are provided so as to correspond to the concave part.
